(19) United States
(12) Patent Application Publication
(10) Pub. No.: US 2010/0052700 A1
(43) Pub. Date: Mar. 4, 2010

(54) CAPACITIVE SENSOR

(75) Inventors: Shigehide YANO, Ukyo-Ku (JP); Koichi SAITO, Ukyo-Ku (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 12/553,676

(22) Filed: Sep. 3, 2009

(30) Foreign Application Priority Data
Sep. 3, 2008 (JP) 2008-226451

(51) Int. Cl. G01R 27/26

(52) U.S. Cl. 324/658

(57) ABSTRACT

A shield electrode is provided in parallel with a sensor electrode. A detecting circuit detects a capacitance formed thereby around the sensor electrode. A capacitance-voltage conversion circuit converts the capacitance into a voltage by repeating a predetermined sequence. A shield electrode drive unit switches an electric state of the shield electrode in synchronization with the predetermined sequence. The shield electrode drive unit switches an electric state of the shield electrode in accordance with an electric state of the sensor electrode.

### BACKGROUND OF THE INVENTION

1. Field of the Invention

The present invention relates to a capacitive sensor that measures a capacitance.

2. Description of the Related Art

In recent electronic apparatuses such as computers, portable telephone terminals and Personal Digital Assistants (PDAs), the apparatuses provided with input devices for operating the apparatuses by putting pressure thereon with users' fingers have become mainstream. As such input devices, joy sticks and touch panels or the like are known.

As such input devices, a capacitance sensor using a change in capacitance formed around an electrode, the change occurring by a user's touch with the electrode, is used.

[Patent Document 1] Japanese Patent Application Laid-open No. 2001-325858

[Patent Document 2] Japanese Patent Application Laid-open No. 2003-511799

An input device using the aforementioned change in a capacitance is provided with a capacitance-voltage conversion circuit for conversing a capacitance into a voltage to be detected. Herein, detection sensitivity of the capacitance-voltage conversion circuit has great influence on performance of the input device because a change in a capacitance occurring when the distance between the two electrodes changes due to contact of a user with the electrode, is as small as several pF or below that. In order to increase the amount of change in the capacitance, it can be considered that the area of the electrode is increased; however, when the area of the electrode is increased, the input device is large in its size. The problem can be solved by increasing the sensitivity of the capacitance-voltage conversion circuit; however, this causes the input device to be more sensitive to the influence of noises from the circumference.

### SUMMARY OF THE INVENTION

The present invention has been made in view of theses issues and an exemplary purpose of an embodiment is to provide a capacitive sensor in which the influence of a noise is suppressed.

An embodiment of the present invention relates to a capacitive sensor. The capacitive sensor comprises: a sensor electrode; a shield electrode that is provided in the vicinity of the sensor electrode; and a detecting circuit that detects a capacitance formed thereby around the sensor electrode. The detecting circuit includes a capacitance-voltage conversion circuit that converts the capacitance into a voltage by repeating a predetermined sequence; and a shield electrode drive unit that switches an electric state of the shield electrode in synchronization with the predetermined sequence.

According to the embodiment, propagation of a noise to the sensor electrode can be shielded by the shield electrode, by switching a state of the shield electrode in synchronization with the sequence.

The shield electrode drive unit may switch an electric state of the shield electrode in accordance with an electric state of the sensor electrode.

The shield electrode drive unit may apply a fixed voltage to the shield electrode at the time when the capacitance-voltage conversion circuit sets the sensor electrode in a high impedance state. The sensor electrode is most sensitive to a noise from the circumstance when the electrode has a high impedance. Accordingly, the noise can be preferably shielded by fixing the potential of the shield electrode at the time.

The fixed voltage may be ground voltage. In this case, the circuit can be simplified.

The shield electrode drive unit may apply voltages to the shield electrode, which are different from each other between at the time when the capacitance-voltage conversion circuit sets the sensor electrode in a high impedance state and at the time when the circuit applies a voltage to the sensor electrode. By changing the potential of the shield electrode in accordance with the voltage applied to the sensor electrode, the capacitance formed between the shield electrode and the sensor electrode can be cancelled.

Another embodiment of the present invention relates to an input device. This device is provided with the capacitive sensor according to any one of the aforementioned embodiments.

Yet another embodiment of the present invention relates to a detecting circuit that is connected to a sensor unit having a sensor electrode and a shield electrode provided in the vicinity of the sensor electrode, and that detects a capacitance formed thereby around the sensor electrode. The detecting circuit comprises: a first voltage applying unit that applies a predetermined first fixed voltage to the sensor electrode in a first state, and that applies a second fixed voltage, which is lower than the first fixed voltage, thereto in a second state; a second voltage applying unit that applies the second fixed voltage to a reference electrode that forms a fixed capacitance around the reference electrode in the first state, and that applies the first fixed voltage thereto in the second state; a first sample hold circuit that averages voltages respectively occurring in the sensor electrode and the reference electrode in the first state to hold an averaged voltage as a first detected voltage; a second sample hold circuit that averages voltages respectively occurring in the sensor electrode and the reference electrode in the second state to hold an averaged voltage as a second detected voltage; an amplification unit that amplifies a potential difference between the first detected voltage and the second detected voltage; and a shield electrode drive unit that switches an electric state of the shield electrode in synchronization with operations of the first and the second voltage applying units and the first and the second sample hold circuits.

The shield electrode drive unit may provide a third fixed voltage to the shield electrode while the first and the second sample hold circuits are sampling the first and the second detected voltages, respectively.

The third fixed voltage may be ground voltage.

The shield electrode drive unit may provide a fourth fixed voltage to the shield electrode while the first voltage applying unit is applying the first fixed voltage to the sensor electrode, and provides a fifth fixed voltage, which is lower than the fourth fixed voltage, to the shield electrode while the first voltage applying unit is applying the second fixed voltage to the sensor electrode.

The first fixed voltage may be equal to the fourth fixed voltage while the second fixed voltage is equal to the fifth fixed voltage.

The amplification unit may be a differential amplifier to which the first and the second detected voltages are inputted. A common-mode noise can be eliminated by subjecting the first and the second detected voltages to differential amplification, allowing a difference between the capacitances to be preferably detected.

The first and the second sample hold circuits may average voltages respectively occurring in the sensor electrode and the reference electrode by connecting the two electrodes together. In this case, transfer of electric charges occurs between the two electrodes, allowing an average value of the voltages occurring in the two electrodes to be obtained.

The second fixed voltage may be ground voltage.

The detecting circuit may be integrated into one piece on a semiconductor integrated circuit (IC). The “integration into one piece” includes the case where all constituents of a circuit are formed on a semiconductor substrate or the case where major constituents of a circuit are integrated into one piece; and part of resistors and capacitors may be provided outside a semiconductor substrate in order to adjust a circuit constant.

Yet another embodiment of the present invention relates to a method for detecting a capacitance formed thereby around the sensor electrode, in a capacitive sensor having the sensor electrode and a shield electrode provided in the vicinity of the sensor electrode. In the method, the following processing are executed: 1. a first step in which a predetermined first fixed voltage is applied to the sensor electrode and a second fixed voltage, which is lower than the first fixed voltage, is applied to a reference electrode that forms a fixed capacitance around the reference electrode; 2. a second step in which the second fixed voltage is applied to the sensor electrode and the first fixed voltage is applied to the reference electrode; 3. a step in which voltages respectively occurring in the sensor electrode and the reference electrode in the first step are averaged such that an averaged voltage is held as a first detected voltage; 4. a step in which voltages respectively occurring in the sensor electrode and the reference electrode in the second step are averaged such that an averaged voltage is held as a second detected voltage; 5. a step in which a potential difference between the first detected voltage and the second detected voltage is amplified; and 6. an electric state of the shield electrode is switched in synchronization with the transitions in the steps 1 to 5.

It is to be noted that any arbitrary combination or rearrangement of the above-described structural components and so forth is effective as and encompassed by the present embodiments. Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a block diagram illustrating an electronic apparatus comprising the input device according to an embodiment;

FIGS. 2A and 2B are respectively a plan view and a cross-sectional view illustrating the structure of a sensor unit;

FIG. 3 is a circuit diagram illustrating the structure of the detecting circuit according to the embodiment;

FIG. 4 is a circuit diagram illustrating a structure example of the detecting circuit in FIG. 3; and

FIG. 5 is operating waveform diagrams of the detecting circuit in FIG. 4.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

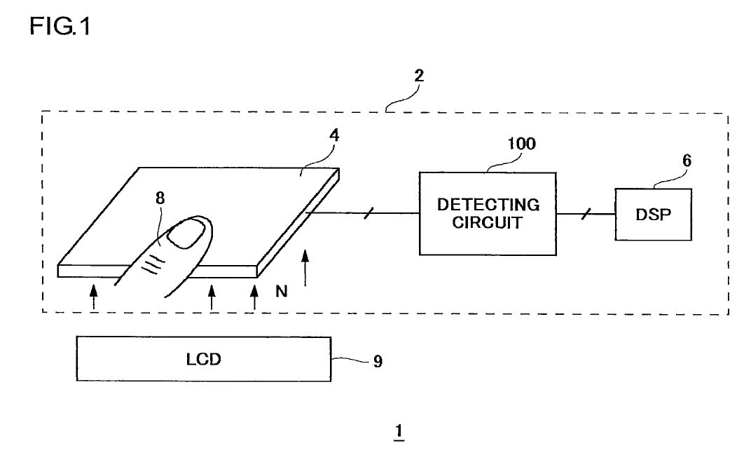

FIG. 1 is a block diagram illustrating an electronic apparatus 1 comprising the input device 2 according to the embodiment. The input device 2 is arranged, for example, on the surface layer of a Liquid Crystal Display (LCD) 9, functioning as a touch panel.

The input device 2 comprises: a sensor unit 4; a detecting circuit 100; and a Digital Signal Processor (DSP) 6. When a user touches or puts pressure on the surface of the sensor unit 4 with a finger 8, a sensor electrode (not illustrated) arranged inside the sensor unit 4 is deformed or displaced, causing a change in a capacitance formed thereby around the sensor electrode. The sensor unit 4 may be a switch provided with a single sensor electrode or an array of a plurality of sensor electrodes arranged in a matrix pattern.

The detecting circuit 100 detects a change in the capacitance in the sensor electrode and outputs data in accordance with a detection result to the DSP 6. The DSP 6 analyzes the data from the detecting circuit 100 to determine existence and type of an input operation of the user. For example, by putting pressure on the sensor unit 4 with the finger 8 of the user, items or objects displayed on the LCD 9 are selected, or input of characters is assisted.

The detecting circuit 100 detects an extremely slight amount of change in the capacitance the sensor electrode forms. Because the sensor unit 4 is arranged on the surface layer of the LCD 9, the sensor electrode inside the sensor unit 4 is sensitive to the influence of noise radiation N form the LCD 9. When a noise is superimposed on the amount of change in the capacitance, operation information from the user cannot be accurately distinguished. Even when the sensor unit is not arranged on the surface layer of the LCD 9, it can be thought that the sensor electrode may be influenced by the noise radiation N from other circuit blocks inside the electronic apparatus 1.

The input device 2 difficult to be influenced by the noise radiation N will be described in detail below.

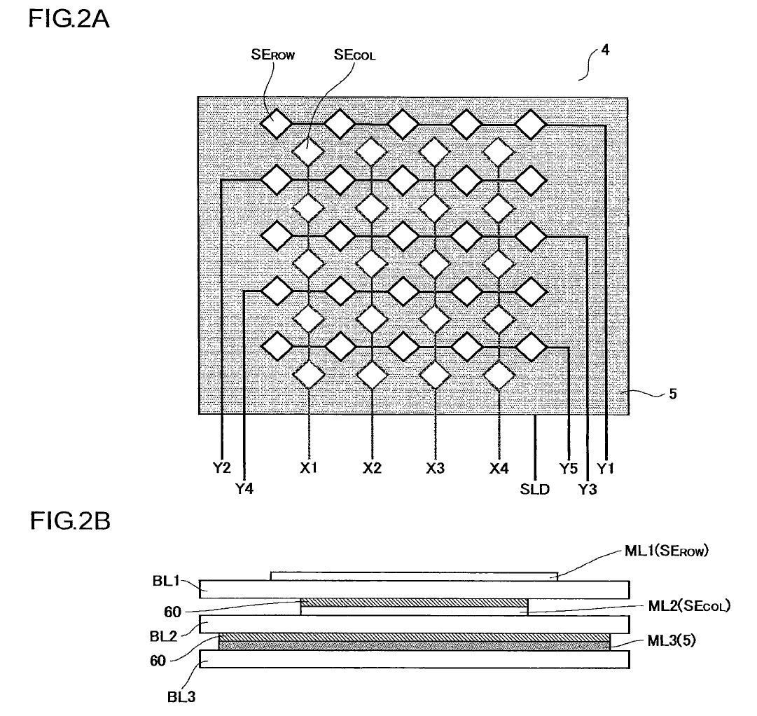

FIGS. 2A and 2B are respectively a plan view and a cross-sectional view illustrating the structure of the sensor unit 4. FIG. 2A is a plan view viewed from above. The sensor unit 4 is provided with a plurality of sensor electrodes SE. The sensor electrodes SE are structured by five rows of row electrodes (represented in black) SE_{ROW}, arranged in the row direction for detecting an input position in the direction, and by four columns of column electrodes (represented in grey) SE_{COL}, arranged in the column direction for detecting that in the direction. The numbers of pieces in the row and the column directions are exemplary only, and any numbers can be adopted.

A signal line Yi is pulled out from the row electrodes SE_{ROW} in the ith row (i: an integer) while a signal line Xj is pulled out from the column electrodes SE_{COL} in the jth column. Further, a signal line SLD is pulled out from the shield electrode 5.

FIG. 2B illustrates a cross-sectional view of the sensor unit 4 in FIG. 2A. The row electrodes SE_{ROW} are formed on a first wiring layer ML1; the column electrodes SE_{COL} on a second wiring layer ML2; and the shield electrode 5 on a third wiring layer ML3.

The wiring layers ML1 to ML3 are transparent electrodes made of indium tin oxide (ITO) or the like, which are formed on the respective surfaces of corresponding base layers BL1 to BL3 by sputtering, or by other methods of applying, heating or fusing the ITO made into ink, on the base layers. For the base layers BL1 to BL3, polyethylene terephthalate (PET), glass and other film-forming agents can be used. Materials other than ITO may be used for the wiring layers ML1 to ML3. A base layer BL and the wiring layer ML adjacent thereto are bonded together with an adhesive 60.

The structure of the sensor unit 4 has been described above. The detecting circuit 100 according to the embodiment reduces the influence of a noise in cooperation with the sensor unit 4 having the sensor electrode SE and the shield electrode 5 provided in the vicinity of the sensor electrode SE.

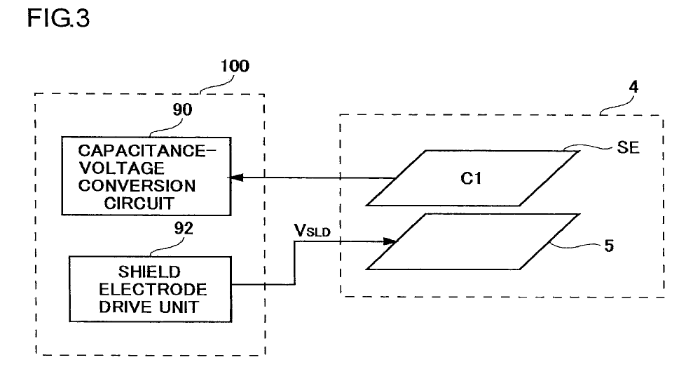

FIG. 3 is a circuit diagram illustrating the structure of the detecting circuit 100 according to the embodiment. The detecting circuit 100 is connected to the sensor unit 4 to detect the capacitance C1 formed thereby around the sensor electrode SE. For simplifying explanation and facilitating understanding, a single sensor electrode SE is only illustrated in FIG. 3.

The detecting circuit 100 comprises: a capacitance-voltage conversion circuit 90; and a shield electrode drive unit 92. The capacitance-voltage conversion circuit 90 converts the capacitance C1 into a voltage Vout by repeating a predetermined sequence. For capacitance-voltage conversion circuits, various techniques are presented, any one of which may be adopted.

The shield electrode drive unit 92 switches an electric state of the shield electrode 5 in synchronization with the predetermined sequence. From another viewpoint, the shield electrode drive unit 92 switches an electric state of the shield electrode 5 in accordance with an electric state of the sensor electrode SE. The electric state means a potential or an impedance. When the sensor electrode SE is sensitive to the influence of a noise from outside, the shield electrode drive unit 92 sets, in accordance with the state of the sensor electrode SE, the shield electrode 5 to the state where the noise is most reduced.

For example, the shield electrode drive unit 92 controls the state of the shield electrode 5 as stated below.

The shield electrode drive unit 92 applies a fixed voltage to the shield electrode 5 at the time when the capacitance-voltage conversion circuit 90 sets the sensor electrode SE in a high impedance state. The fixed voltage is preferably ground voltage 0 V, but other values such as a power supply voltage Vdd or the midpoint voltage Vdd/2 may be adopted. The fixed voltage may be set to a value by which the noise is most reduced. When the sensor electrode has a high impedance, the shield electrode is most sensitive to the influence of a noise from outside. Accordingly, if a potential of the shield electrode 5 is fixed at this time, the noise can be preferably shielded.

In addition, the shield electrode drive unit 92 may apply voltages to the shield electrode 5, which are different from each other between at the time when the capacitance-voltage conversion circuit 90 sets the sensor electrode SE in a high impedance state and at the time when the circuit applies a voltage to the sensor electrode. By changing the potential of the shield electrode 5 in accordance with the voltage applied to the sensor electrode SE, the capacitance formed between the shield electrode 5 and the sensor electrode SE can be cancelled.

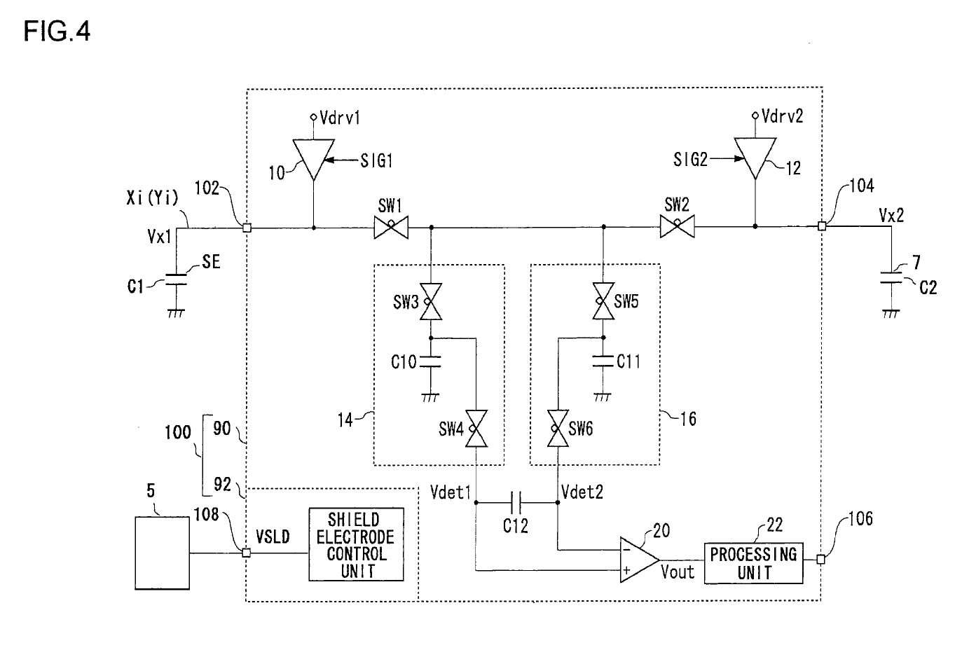

FIG. 4 is a circuit diagram illustrating a structure example of the detecting circuit 100 in FIG. 3. The detecting circuit 100 is a functional IC integrated into one piece on a semiconductor IC circuit, which comprises: a first terminal 102; a second terminal 104; and an output terminal 106. The sensor electrode SE is connected to the first terminal 102.

The reference electrode 7 is connected to the second terminal 104. The reference electrode 7 forms the capacitance C2 around the electrode 7 in the same way as the sensor electrode SE. Because the capacitance C2 has an unchanged fixed value, it is also called a reference capacitance C2.

The capacitance-voltage conversion circuit 90 detects a change in the capacitance C1 the sensor electrode SE forms, and outputs data in accordance with the change in the capacitance from the output terminal 106 to outside.

The capacitance-voltage conversion circuit 90 comprises: a first voltage applying unit 10; a second voltage applying unit 12; a first sample hold circuit 14; a second sample hold circuit 16; an amplification unit 20; a processing unit 22; a capacitor C12; a first switch SW1; and a second switch SW2. In the present embodiment, the switches of the first switch SW1 to the sixth switch SW6 are structured with transfer gates using transistors.

The first voltage applying unit 10 applies a predetermined first fixed voltage to the sensor electrode SE in a first state while applies a second fixed voltage, which is lower than the first fixed voltage, thereto in a second state. Specifically, the first voltage applying unit 10 outputs the inputted first drive voltage Vdrv1 while a first control signal SIG1 is being at the high-level, and makes the output terminal have a high impedance while the signal SIG1 is being at the low-level. The first drive voltage Vdrv is the predetermined first fixed voltage in the first state while is switched to the second fixed voltage, which is lower than the first fixed voltage, in the second state. In the present embodiment, the first fixed voltage is set to the power supply voltage Vdd while the second fixed voltage to ground voltage 0 V.

The second voltage applying unit 12 applies the second fixed voltage (ground voltage 0 V) to the reference electrode 7 in the first state while applies the first fixed voltage (power supply voltage Vdd) thereto in the second state. Specifically, the second voltage applying unit 12 outputs the inputted second drive voltage Vdrv2 while a second control signal SIG2 is being at the high-level, and makes the output terminal have a high impedance while the signal SIG2 is being at the low-level. The second drive voltage Vdrv2 is equal to ground voltage 0 V of the second fixed voltage in the first state while is equal to the power supply voltage Vdd of the first fixed voltage in the second state.

That is, the sensor electrode SE is applied with the first fixed voltage in the first state while is applied with the second fixed voltage in the second state, by the first voltage applying unit 10; on the other hand, the reference electrode 7 is applied with the second fixed voltage in the first state while is applied with the first fixed voltage in the second state, by the second voltage applying unit 12. As stated above, the sensor electrode SE and the reference electrode 7, which are respectively connected to the first terminal 102 and the second terminal 104, are complimentarily applied with voltages, the high level and the low-level of which are opposite to each other in the first and the second states.

The first switch SW1 and the second switch SW2 are provided between the first terminal 102 and the second terminal 104. When the first switch SW1 and the second switch SW2 are both switched on, the sensor electrode SE and the reference electrode 7 are connected together. As a result, electric charges stored in the sensor electrode SE and the reference electrode 7 are transferred between the two electrodes, causing voltages Vx1 and Vx2 occurring in the respective electrodes to be averaged.

The first sample hold circuit 14 averages the voltages Vx1 and Vx2 respectively occurring in the sensor electrode SE and the reference electrode 7 in the first state to hold an averaged voltage as a first detected voltage Vdet1. The first sample hold circuit 14 includes a third switch SW3, a fourth switch SW4 and a capacitor C10. When the third switch SW3 is switched on, the averaged voltage between the voltages Vx1 and Vx2 is sampled as the first detected voltage Vdet1 while the first detected voltage Vdet1 is held when the third switch SW3 is switched off.

A second sample hold circuit 16 averages the voltages Vx1 and Vx2 respectively occurring in the sensor electrode SE and the reference electrode 7 in the second state to hold an averaged voltage as a second detected voltage Vdet2. The second sample hold circuit 16 is structured in the same way as the first sample hold circuit 14.

The amplification unit 20 is a differential amplifier to which the first detected voltage Vdet1 and the second detected voltage Vdet2 are inputted, and that subjects the two voltages to differential amplification. The capacitor C12 is provided between differential input terminals of the amplification unit 20. A voltage amplified by the amplification unit 20 is inputted to the processing unit 22.

The processing unit 22 subjects the detected voltage Vout outputted from the amplification unit 20, to A/D conversion, and outputs the voltage from the output terminal 106 as digital data after subjecting the voltage to predetermined signal processing. When the detected voltage Vout is outputted as it is as an analog voltage, the processing unit 22 is not required.

The shield electrode drive unit 92 drives the shield electrode 5 in synchronization with the sequence of the capacitance-voltage conversion circuit 90.

The shield electrode drive unit 92 provides ground voltage (0 V) to the shield electrode 5 while the first sample hold circuit 14 and the second sample hold circuit 16 are respectively sampling the first detected voltage Vdet1 and the second detected voltage Vdet2.

The shield electrode drive unit 92 provides a fourth fixed voltage to the shield electrode 5 while the first voltage applying unit 10 is applying the first fixed voltage (Vdd) to the sensor electrode SE, and provides a fifth voltage, which is lower than the fourth voltage, to the shield electrode 5 while the first voltage applying unit 10 is applying the second fixed voltage (0 V) to the sensor electrode SE.

Preferably, the fourth fixed voltage is set to be equal to the first fixed voltage. Namely, the fourth fixed voltage is the power supply voltage Vdd. Further, the fifth fixed voltage is set to be equal to the second fixed voltage. Namely, the fifth fixed voltage is ground voltage 0 V.

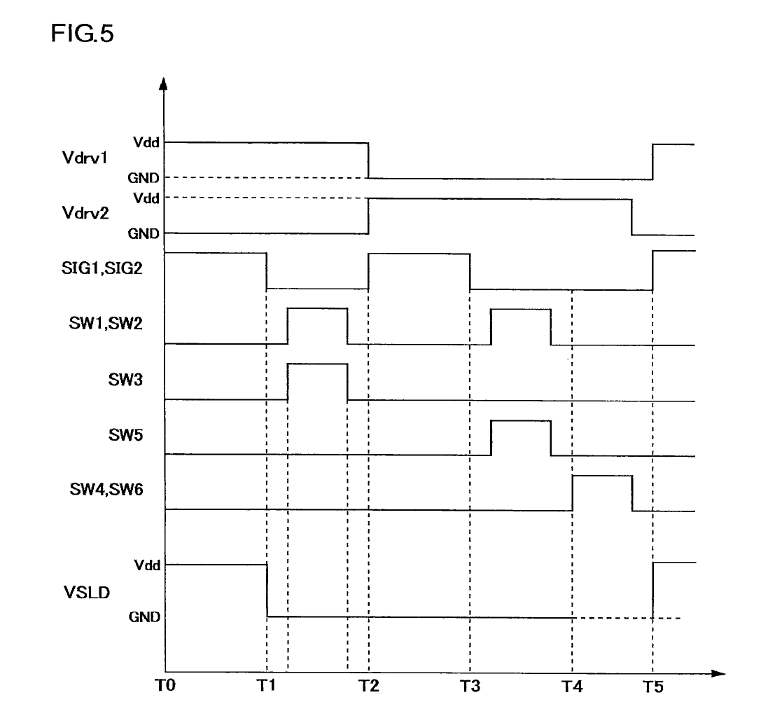

Operations of the detecting circuit 100 structured as stated above will be described below. FIG. 5 is operating waveform diagrams of the detecting circuit 100. The waveform diagrams in FIG. 5 illustrate, from top to bottom, the first drive voltage Vdrv1, the second drive voltage Vdrv2, the first control signal SIG1, the second control signal SIG2, on/off states of the first switch SW1 to the sixth switch SW6, and the voltage VSLD applied to the shield electrode 5.

In FIG. 5, the high-levels of the first switch SW1 to the sixth switch SW6 correspond to on states while the low-levels thereof to off states. In FIG. 5, the period between the time T0 and the time T2 represents the first state while the period between T2 and T4 the second state.

During the first state period between T0 and T2, the first drive voltage Vdrv1 inputted to the first voltage applying unit 10 is the power supply voltage Vdd while the second drive voltage Vdrv2 inputted to the second voltage applying unit 12 is ground voltage 0 V.

During the period between T0 and T1, the first control signal SIG1 and the second control signal SIG2 are both at the high-level. As a result, the sensor electrode SE is charged with the first drive voltage Vdrv1=Vdd while the reference electrode 7 with the second drive voltage Vdrv2=0 V. During the period, the shield electrode drive unit 92 makes the potential VSLD of the shield electrode 5 equal to that of the sensor electrode SE, i.e., the power supply voltage Vdd. As a result, the influence by a parasitic capacitance occurring between the shield electrode 5 and the sensor electrode SE can be reduced.

When the first control signal SIG1 and the second control signal SIG2 are at the low-level at the time T1, voltage application to the sensor electrode SE and the reference electrode 7 are halted.

Subsequently, the first switch SW1 and the second switch SW2 are switched on followed by transfer of the stored electric charges between the sensor electrode SE and the reference electrode 7, allowing the voltages Vx1 and Vx2 respectively occurring in the sensor electrode SE and the reference electrode 7 to be averaged.

The third switch SW3 is switched on at the same time when the first switch SW1 and the second switch SW2 are switched on, allowing the first sample hold circuit 14 to sample/hold the averaged voltage Vx as the first detected voltage Vdet1.

During the period between T1 and T2, output impedances of the first voltage applying unit 10 and the second voltage applying unit 12 have high impedances, causing impedance of the sensor electrode SE to be high. During the period, the shield electrode drive unit 92 applies ground voltage 0 V to the shield electrode 5, allowing a noise to be shielded.

A transition to the second state is made at the time T2. During the second state period between T2 and T4, the first drive voltage Vdrv1 inputted to the first voltage applying unit 10 is ground voltage 0 V while the second drive voltage Vdrv2 inputted to the second voltage applying unit 12 is the power voltage Vdd. During the period between T2 and T3, the first control signal SIG1 and the second control signal SIG2 are at the high-level again. As a result, the sensor electrode SE is charged with the first drive voltage Vdrv1=0 V while the reference electrode 7 is with the second drive voltage Vdrv2=Vdd. As a result of the charge, the voltages Vx1 and Vx2 respectively occurring in the sensor electrode SE and the reference electrode 7 are: Vx1=0 and Vx2=Vdd, respectively.

During the period between T2 and T3, the shield electrode drive unit 92 makes the potential VSLD of the shield electrode 5 equal to that of the sensor electrode SE, i.e., ground voltage 0 V. As a result, the influence by a parasitic capacitance occurring between the shield electrode 5 and the sensor electrode SE can be reduced.

When the first control signal SIG1 and the second control signal SIG2 are at the low-level at the time T3, voltage application to the sensor electrode SE and the reference electrode 7 is halted.

Subsequently, the first switch SW1 and the second switch SW2 are switched on followed by transfer of the stored electric charges between the sensor electrode SE and the reference electrode 7, allowing the voltages Vx1 and Vx2 occurring in each electrode to be averaged.

The fifth switch SW5 is switched on at the same time when the first switch SW1 and the second switch SW2 are switched on, allowing the second sample hold circuit 16 to sample/hold the averaged voltage Vx as the second detected voltage Vdet2.

During the period between T3 and T4, output impedances of the first voltage applying unit 10 and the second voltage applying unit 12 have high impedances, causing impedance of the sensor electrode SE to be high. During the period, the shield electrode drive unit 92 applies ground voltage 0 V to the shield electrode 5, allowing a noise to be shielded.

When the fourth switch SW4 and the sixth switch SW6 are switched on at the time T4, the first sample hold circuit 14 and the second sample hold circuit 16 respectively output the first detected voltage Vdet1 and the second detected voltage Vdet2 thus sampled/held, to the amplification unit 20.

The first detected voltage Vdet1 and the second detected voltage Vdet2 are subjected to differential amplification by the amplification unit 20. When a differential amplification gain of the amplification unit 20 is Av, the output voltage Vout of the unit 20 is represented by the following equation: Vout=Av×(Vdet1−Vdet2). A transition to the first state is made at the time T5, and the same processing are repeated.

A noise to the sensor electrode SE from outside can be preferably shielded through this sequence, allowing a change in the capacitance C1 to be detected with high sensitivity.

The features of the detecting circuit 100 according to the embodiment can also be understood as follows: the detecting circuit 100 comprises the shield electrode drive unit 92 that can make the potential of the shield electrode 5 fixed to any value. As a result, the potential of the shield electrode can be set such that the influence of a noise to the sensor electrode SE is most reduced.

While the preferred embodiments of the present invention have been described using specific terms, such description is for illustrative purposes only, and it is to be understood that changes and variations may be made without departing from the spirit or scope of the appended claims.

What is claimed is:

1. A capacitive sensor comprising:
a sensor electrode;
a shield electrode that is provided in the vicinity of the sensor electrode; and
a detecting circuit that detects a capacitance formed thereby around the sensor electrode, wherein the detecting circuit includes a capacitance-voltage conversion circuit that converts the capacitance into a voltage by repeating a predetermined sequence, and a shield electrode drive unit that switches an electric state of the shield electrode in synchronization with the predetermined sequence.

2. The capacitive sensor according to claim 1, wherein the shield electrode drive unit switches an electric state of the shield electrode in accordance with an electric state of the sensor electrode.

3. The capacitive sensor according to claim 1, wherein the shield electrode drive unit applies a fixed voltage to the shield electrode at the time when the capacitance-voltage conversion circuit sets the sensor electrode in a high impedance state.

4. The capacitive sensor according to claim 3, wherein the fixed voltage is ground voltage.

5. The capacitive sensor according to claim 1, wherein the shield electrode drive unit applies voltages to the shield electrode, which are different from each other between at the time when the capacitance-voltage conversion circuit sets the sensor electrode in a high impedance state and at the time when the capacitance-voltage conversion circuit applies a voltage to the sensor electrode.

6. An input device comprising the capacitive sensor according to claim 1.

7. A detecting circuit that is connected to a sensor unit having a sensor electrode and a shield electrode provided in the vicinity of the sensor electrode, and that detects a capacitance formed thereby around the sensor electrode, the detecting circuit comprising:
a first voltage applying unit that applies a predetermined first fixed voltage to the sensor electrode in a first state, and that applies a second fixed voltage, which is lower than the first fixed voltage, thereto in a second state;
a second voltage applying unit that applies the second fixed voltage to a reference electrode that forms a fixed capacitance around the reference electrode in the first state, and that applies the first fixed voltage thereto in the second state;
a first sample hold circuit that averages voltages respectively occurring in the sensor electrode and the reference electrode in the first state to hold an averaged voltage as a first detected voltage;
a second sample hold circuit that averages voltages respectively occurring in the sensor electrode and the reference electrode in the second state to hold an averaged voltage as a second detected voltage;
an amplification unit that amplifies a potential difference between the first detected voltage and the second detected voltage; and
a shield electrode drive unit that switches an electric state of the shield electrode in synchronization with operations of the first and the second voltage applying units and the first and the second sample hold circuits.

8. The detecting circuit according to claim 7, wherein the shield electrode drive unit provides a third fixed voltage to the shield electrode while the first and the second sample hold circuits are sampling the first and the second detected voltages, respectively.

9. The detecting circuit according to claim 8, wherein the third fixed voltage is ground voltage.

10. The detecting circuit according to claim 7, wherein the shield electrode drive unit provides a fourth fixed voltage to the shield electrode while the first voltage applying unit is applying the first fixed voltage to the sensor electrode, and provides a fifth fixed voltage, which is lower than the fourth fixed voltage, to the shield electrode while the first voltage applying unit is applying the second fixed voltage to the sensor electrode.

11. The detecting circuit according to claim 10, wherein the first fixed voltage is equal to the fourth fixed voltage while the second fixed voltage is equal to the fifth fixed voltage.

12. The detecting circuit according to claim 7, wherein the amplification unit is a differential amplifier to which the first and the second detected voltages are inputted.

13. The detecting circuit according to claim 7, wherein the first and the second sample hold circuits average voltages respectively occurring in the sensor electrode and the reference electrode by connecting the sensor electrode and the reference electrode together.

14. The detecting circuit according to claim 7, wherein the second fixed voltage is ground voltage.

15. The detecting circuit according to claim 7 integrated into one piece on a semiconductor integrated circuit.

16. A method for detecting a capacitance formed thereby around a sensor electrode, in a capacitive sensor having the sensor electrode and a shield electrode provided in the vicinity of the sensor electrode, the method comprising:
a first step of applying a predetermined first fixed voltage to the sensor electrode and applying a second fixed voltage, which is lower than the first fixed voltage, to a reference electrode that forms a fixed capacitance around the reference electrode;
a second step of applying the second fixed voltage to the sensor electrode and applying the first fixed voltage to the reference electrode;
a step of averaging voltages respectively occurring in the sensor electrode and the reference electrode in the first step such that an averaged voltage is held as a first detected voltage;
a step of averaging voltages respectively occurring in the sensor electrode and the reference electrode in the second step such that an averaged voltage is held as a second detected voltage;
a step of amplifying a potential difference between the first detected voltage and the second detected voltage; and
a step of switching an electric state of the shield electrode in synchronization with the transition in each step.
